(19) United States
(12) Patent Application Publication
(10) Pub. No.: US 2025/0151629 A1
(43) Pub. Date: May 8, 2025

(54) MAGNETORESISTIVE RANDOM ACCESS MEMORY DEVICE AND METHOD OF MANUFACTURING THE SAME

(71) Applicant: Samsung Electronics Co., Ltd., Suwon-si (KR)

(72) Inventor: Hyungjong JEONG, Suwon-si (KR)

(73) Assignee: Samsung Electronics Co., Ltd., Suwon-si (KR)

(21) Appl. No.: 18/799,264

(22) Filed: Aug. 9, 2024

(30) Foreign Application Priority Data
Nov. 6, 2023 (KR) 10-2023-0151985

(51) Int. Cl. H10N 50/10; H01L 23/528; H10B 61/00; H10N 50/01; H10N 50/80

(52) U.S. Cl. CPC H10N 50/10; H01L 23/5283; H10B 61/20; H10N 50/01; H10N 50/80

(57) ABSTRACT

A magnetoresistive random access memory device may include a wiring structure on a substrate, an etch stop layer on the wiring structure, an interlayer insulation layer on the etch stop layer, a plurality of contact structures penetrating the interlayer insulation layer and the etch stop layer to contact the wiring structure, each of the plurality of contact structures including a first portion having a sidewall facing the interlayer insulation layer and a second portion having a sidewall facing the etch stop layer, and a plurality of magnetic tunnel junction structures on the plurality of contact structures and connected to corresponding ones of the plurality of contact structures, respectively, wherein a first width of the first portion in a first horizontal direction is greater than a second width of the second portion in the first horizontal direction.

### CROSS-REFERENCE TO RELATED APPLICATION

This application is based on and claims priority under 35 U.S.C. § 119 to Korean Patent Application No. 10-2023-0151985, filed on Nov. 6, 2023, in the Korean Intellectual Property Office, the disclosure of which is incorporated by reference herein in its entirety.

### BACKGROUND

The inventive concepts relate to magnetoresistive random access memory devices and methods of manufacturing the same.

Many researches are being conducted on electronic devices that utilize the magnetoresistance properties of magnetic tunnel junction (MTJ). As MTJ cells of highly-integrated magnetic random access memory (MRAM) devices become miniaturized, wires and/or contacts constituting the miniaturized MTJ cells need to be miniaturized. Various studies are being conducted to improve the reliability of magnetoresistive random access memory devices while satisfying demands for high integration and/or low power consumption.

### SUMMARY

Some example embodiments of the inventive concepts provide magnetoresistive random access memory devices with improved reliability.

Some example embodiments of the inventive concepts provide methods of manufacturing a magnetoresistive random access memory device with improved reliability.

According to an example embodiment of the inventive concepts, a magnetoresistive random access memory device may include a wiring structure on a substrate, an etch stop layer on the wiring structure, an interlayer insulation layer on the etch stop layer, a plurality of contact structures penetrating the interlayer insulation layer and the etch stop layer to contact the wiring structure, each of the plurality of contact structures including a first portion having a sidewall facing the interlayer insulation layer and a second portion having a sidewall facing the etch stop layer, and a plurality of magnetic tunnel junction structures on the plurality of contact structures and connected to corresponding ones of the plurality of contact structures, respectively, wherein a first width of the first portion in a first horizontal direction is greater than a second width of the second portion in the first horizontal direction.

According to an example embodiment of the inventive concepts, a magnetoresistive random access memory device may include a wiring structure on a substrate, an etch stop layer on the wiring structure, an interlayer insulation layer on the etch stop layer, a plurality of contact structures penetrating the interlayer insulation layer, the etch stop layer, and a portion of the wiring structure to contact the wiring structure, each of the plurality of contact structures including a first portion having a sidewall facing the interlayer insulation layer, a second portion having a sidewall facing the etch stop layer, and a third portion extending into the wiring structure, and a plurality of magnetic tunnel junction structures on the plurality of contact structures and connected to corresponding ones of the plurality of contact structures, respectively, wherein the second portion includes a lower portion, an upper portion on the lower portion, and an inflection portion defined between the lower portion and the upper portion, the upper portion having a greater width in a first horizontal direction than the lower portion and the sidewall of the first portion has a first angle with respect to a top surface of the etch stop layer, a sidewall of the lower portion of the second portion has a second angle with respect to the top surface of the etch stop layer, and the second angle is greater than the first angle.

According to an example embodiment of the inventive concepts, a method of manufacturing a magnetoresistive random access memory device may include forming a wiring structure on a substrate, forming, on the wiring structure, an etch stop layer and a preliminary insulation layer, which includes a plurality of first contact openings exposing the etch stop layer, forming a spacer layer conformally covering the plurality of first contact openings, forming a plurality of second contact openings exposing the wiring structure by removing a portion of the spacer layer and the etch stop layer, forming a plurality of third contact openings by removing the spacer layer, and forming a plurality of contact structures filling the plurality of third contact openings, respectively.

### BRIEF DESCRIPTION OF THE DRAWINGS

Example embodiments of the inventive concepts will be more clearly understood from the following detailed description taken in conjunction with the accompanying drawings in which:

FIG. 1 is a circuit diagram showing a unit memory cell of a magnetoresistive random access memory device according to an example embodiment;

FIG. 2A is a plan view of a magnetoresistive random access memory device according to an example embodiment;

FIG. 2B is a cross-sectional view taken along a line X1-X1′ of FIG. 2A;

FIG. 3A is an enlarged view of a region “EX1” of FIG. 2B;

FIG. 3B is an enlarged view of a region “EX2” of FIG. 3A;

FIG. 4 is a cross-sectional view of a magnetoresistive random access memory device according to an example embodiment and shows a region corresponding to the region EX1 in FIG. 2B;

FIG. 4 is a cross-sectional view of a magnetoresistive random access memory device according to an example embodiment;

FIG. 6 is a flowchart of a method of manufacturing a magnetoresistive random access memory device, according to an example embodiment; and

FIGS. 7A to 7K are cross-sectional views showing according to a process sequence a method of manufacturing a magnetoresistive random access memory device according to an example embodiment.

### DETAILED DESCRIPTION

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C, or any combination thereof. Likewise, A and/or B means A, B, or A and B.

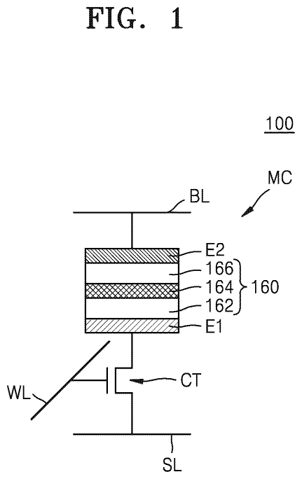

FIG. 1 is a circuit diagram showing a unit memory cell MC of a magnetoresistive random access memory device 100 according to an example embodiment.

According to an example embodiment, the magnetoresistive random access memory device 100 may include a memory cell MC. The memory cell MC may include a first electrode E1, a second electrode E2, and a magnetic tunnel junction structure 160 between the first electrode E1 and the second electrode E2. The magnetic tunnel junction structure 160 may be connected to a cell transistor CT through the first electrode E1.

According to an example embodiment, a gate of the cell transistor CT may be connected to a word line WL. One electrode of the cell transistor CT may be connected to a bit line BL through the magnetic tunnel junction structure 160. For example, the bit line BL may be connected to the magnetic tunnel junction structure 160 through the second electrode E2. The other electrode of the cell transistor CT may be connected to a source line SL.

According to an example embodiment, the magnetic tunnel junction structure 160 may include a first magnetic pattern 162, a tunnel barrier pattern 164, and a second magnetic pattern 166. The tunnel barrier pattern 164 may be disposed between the first magnetic pattern 162 and the second magnetic pattern 166. One end of the first magnetic pattern 162 may be connected to the cell transistor CT, and the other end of the first magnetic pattern 162 may be connected to the tunnel barrier pattern 164. One end of the second magnetic pattern 166 may be connected to the tunnel barrier pattern 164, and the other end of the second magnetic pattern 166 may be connected to the bit line BL.

The magnetic tunnel junction structure 160 may be a variable resistor device that may be switched between two resistance states by an electric pulse applied thereto. The first magnetic pattern 162 has a magnetization easy axis in one direction, and the magnetization direction thereof may be fixed. The second magnetic pattern 166 shares the easy magnetization axis and may have a variable magnetization direction depending on conditions. The resistance value of the magnetic tunnel junction structure 160 may vary depending on the magnetization directions of the first magnetic pattern 162 and the second magnetic pattern 166. For example, when the magnetization direction in the second magnetic pattern 166 is parallel to the magnetization direction in the first magnetic pattern 162, the magnetic tunnel junction structure 160 has a first resistance value and stores data ‘0’. For example, when the magnetization direction in the second magnetic pattern 166 is anti-parallel to the magnetization direction in the first magnetic pattern 162, the magnetic tunnel junction structure 160 has a second resistance value and stores data ‘1’.

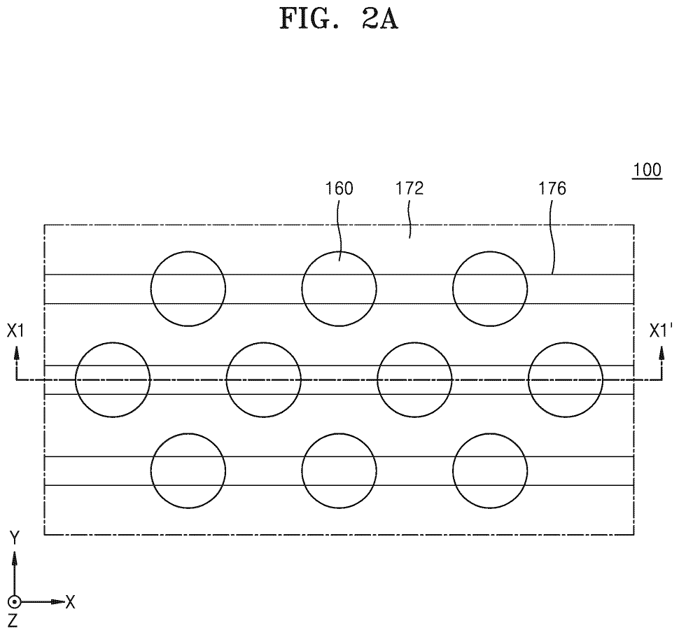

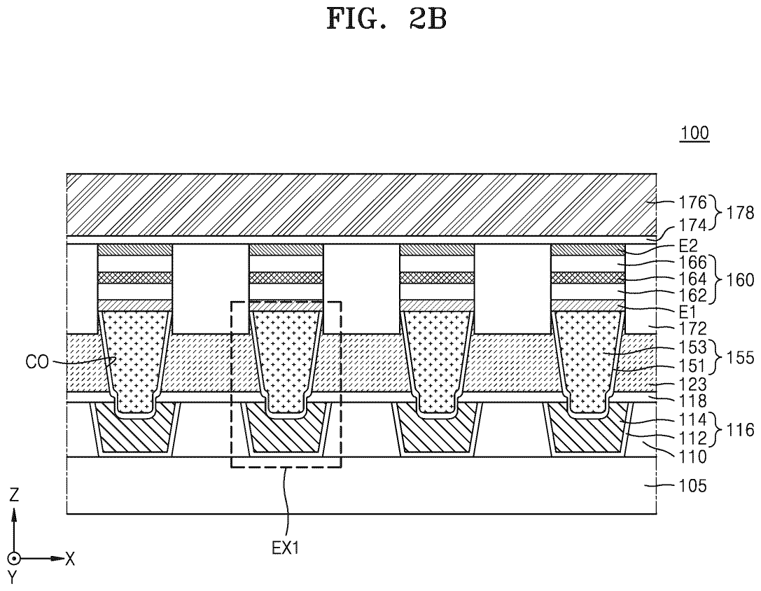

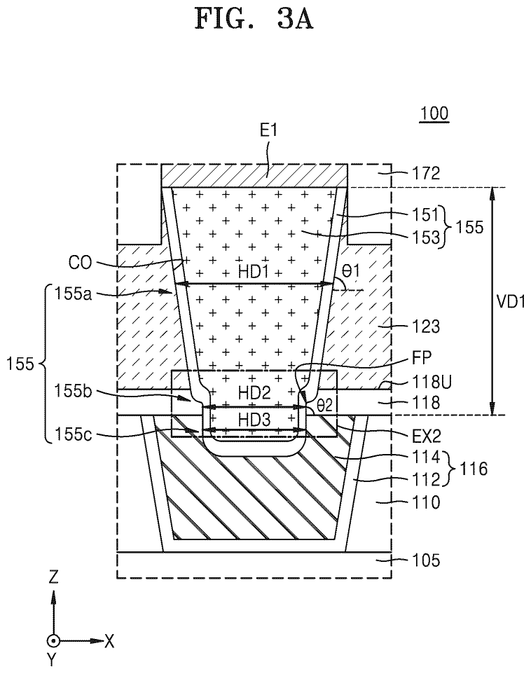

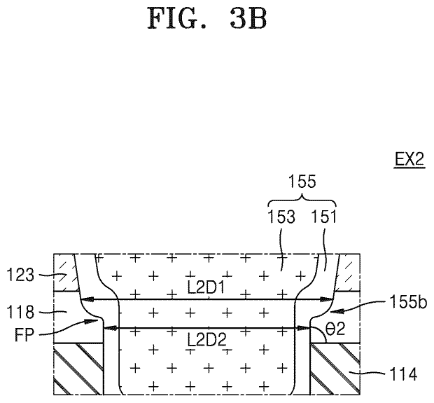

FIG. 2A is a plan view of the magnetoresistive random access memory device 100 according to an example embodiment. FIG. 2B is a cross-sectional view taken along a line X1-X1′ of FIG. 2A. FIG. 3A is an enlarged view of a region “EX1” of FIG. 2B. FIG. 3B is an enlarged view of a region “EX2” of FIG. 3A.

Referring to FIGS. 2A to 3B, the magnetoresistive random access memory device 100 may include a substrate 105, a wiring structure 116 on the substrate 105, a first interlayer insulation layer 110, an etch stop layer 118, a second interlayer insulation layer 123, a plurality of contact structures 155, the first electrode E1, a plurality of magnetic tunnel junction structures 160, the second electrode E2, and an isolation insulation layer 172.

According to some example embodiments, the first interlayer insulation layer 110 may be disposed on the substrate 105, and the wiring structure 116 may be connected to the substrate 105 by penetrating through the first interlayer insulation layer 110.

According to some example embodiments, the substrate 105 may include a semiconductor element such as Si or Ge or a compound semiconductor such as SiC, GaAs, InAs, or InP. The substrate 105 may include a semiconductor substrate and at least one insulation layer, which is formed on the semiconductor substrate, or structures including at least one conductive region. The conductive region may include a well doped with impurities or a structure doped with impurities. A device isolation region (not shown) defining a plurality of active regions may be formed in the substrate 105. The device isolation region may include an oxide film, a nitride film, or a combination thereof. For example, the structures may include the cell transistor CT, the word line WL, and the source line SL described above with reference to FIG. 1. The wiring structure 116 may be electrically connected to at least some of the structures.

According to some example embodiments, the wiring structure 116 may include a conductive line extending in the horizontal direction (X direction and/or Y direction) and/or a contact extending in the vertical direction (Z direction), on the substrate 105. According to some example embodiments, the wiring structure 116 may include a wiring barrier pattern 112 and a wiring pattern 114. According to some embodiments, the wiring pattern 114 may penetrate the first interlayer insulation layer 110, and the wiring barrier pattern 112 may be between the wiring pattern 114 and the first interlayer insulation layer 110 and between the wiring pattern 114 and the substrate 105.

According to some example embodiments, the first interlayer insulation layer 110 may include an oxide film, a nitride film, an ultra-low k (ULK) film having an ultra-low dielectric constant k from about 2.2 to about 2.4, or a combination thereof. According to some example embodiments, the first interlayer insulation layer 110 may include a tetraethylorthosilicate (TEOS) film, a high density plasma (HDP) film, a boro-phospho-silicate glass (BPSG) film, a flowable chemical vapor deposition (FCVD) oxide film, a SiON film, a SiN film, a SiOC film, a SiCOH film, or a combination thereof, but is not limited thereto. The terms such as “SiON”, “SiN”, and “SiOC” used herein refer to materials composed of elements included in the respective terms and are not chemical formulas indicating stoichiometric relationships.

According to some example embodiments, the wiring barrier pattern 112 may include Ti, Ta, TiN, TaN, or a combination thereof, and the wiring pattern 114 may include W, Al, Co, Cu, Ru, Mn, or a combination thereof. However, the inventive concepts are not limited thereto.

According to some example embodiments, the etch stop layer 118 and the second interlayer insulation layer 123 may be arranged on the wiring structure 116 and the first interlayer insulation layer 110, and the plurality of contact structures 155 may each contact the wiring structure 116 by penetrating the etch stop layer 118 and the second interlayer insulation layer 123. According to some example embodiments, the plurality of contact structures 155 may be arranged to be spaced apart from each other in the horizontal direction (X direction and/or Y direction) on the wiring structure 116.

According to some example embodiments, the second interlayer insulation layer 123 may include a silicon oxide film (e.g., a TEOS film). According to some example embodiments, the etch stop layer 118 may include an insulation material that has an etch selectivity with respect to the second interlayer insulation layer 123. For example, the etch stop layer 118 may include silicon boron nitride (SiBN), silicon carbonitride (SiCN), silicon nitride (SiN), or a combination thereof.

According to some example embodiments, the plurality of contact structures 155 may each include a contact barrier pattern 151 that covers the inner wall of a contact opening CO, which penetrate portions of the second interlayer insulation layer 123, the etch stop layer 118, and the wiring pattern 114 in the vertical direction (Z direction), and a conductive plug 153 that fills the contact opening CO on the contact barrier pattern 151. According to some example embodiments, the contact barrier pattern 151 may include a portion between the conductive plug 153 and the second interlayer insulation layer 123, a portion between the conductive plug 153 and the etch stop layer 118, and a portion between the conductive plug 153 and the wiring structure 116.

According to some example embodiments, the contact barrier pattern 151 may include Ti, Ta, TiN, TaN, or a combination thereof. According to some example embodiments, the conductive plug 153 may include W, Co, Cu, Ru, Mn, or a combination thereof.

According to some example embodiments, the plurality of magnetic tunnel junction structures 160 may be individually disposed on the plurality of contact structures 155, respectively. According to some example embodiments, the plurality of contact structures 155 may each extend in the vertical direction (Z direction) between each of the plurality of magnetic tunnel junction structures 160 and the wiring structure 116. The first electrode E1 may be disposed between the plurality of magnetic tunnel junction structures 160 and the plurality of contact structures 155, and the second electrode E2 may be spaced apart from the first electrode E1 in the vertical direction (Z direction) with a corresponding one of the plurality of magnetic tunnel junction structures 160 therebetween. For example, the first electrode E1, one magnetic tunnel junction structure 160, and the second electrode E2 may be sequentially stacked on each of the plurality of contact structures 155 in the vertical direction (Z direction). For example, one end of each of the plurality of contact structures 155 may be in contact with the first electrode E1 in the vertical direction (Z direction), and the other end of each of the plurality of contact structures 155 may be in contact with the wiring structure 116.

According to some example embodiments, the first electrode E1 and the second electrode E2 may each include a metal film, a conductive metal oxide film, a conductive metal nitride film, a conductive metal oxynitride film, or a combination thereof.

According to some example embodiments, the plurality of magnetic tunnel junction structures 160 each may include the first magnetic pattern 162, the tunnel barrier pattern 164, and the second magnetic pattern 166 that are sequentially stacked in the vertical direction (Z direction) on the first electrode E1. For example, the first magnetic pattern 162 may be spaced apart from the second magnetic pattern 166 in the vertical direction (Z direction) with the tunnel barrier pattern 164 therebetween.

According to some example embodiments, the first magnetic pattern 162 and the second magnetic pattern 166 may each include a ferromagnetic material. According to some example embodiments, the first magnetic pattern 162 may further include an anti-ferromagnetic material to fix the magnetization direction of the ferromagnetic material in a first magnetic structure MS1.

According to some example embodiments, the first magnetic pattern 162 may be configured to have a fixed magnetization direction in the horizontal direction (X direction and/or Y direction) with respect to the top surface 118U of the etch stop layer 118. In this case, the second magnetic pattern 166 may be configured such that the magnetization direction of the second magnetic pattern 166 is fixed in a direction parallel or anti-parallel to the fixed magnetization direction as a first voltage or a second voltage is applied to the magnetic tunnel junction structure 160.

According to some other example embodiments, the first magnetic pattern 162 may be configured to have a fixed magnetization direction in the vertical direction (Z direction) with respect to the top surface 118U of the etch stop layer 118. In this case, the second magnetic pattern 166 may be configured such that the magnetization direction of the second magnetic pattern 166 is fixed in a direction parallel or anti-parallel to the fixed magnetization direction as a first voltage or a second voltage is applied to the magnetic tunnel junction structure 160.

According to some example embodiments, the first magnetic pattern 162 may include multiple layers stacked in the vertical direction (Z direction). For example, the first magnetic pattern 162 may include at least one ferromagnetic pattern and at least one anti-ferromagnetic pattern. When the ferromagnetic pattern and the anti-ferromagnetic pattern each include multiple layers, the multiple layers of the ferromagnetic pattern and the multiple layers of the anti-ferromagnetic pattern may include different materials. According to some example embodiments, the ferromagnetic pattern may include iron (Fe), nickel (Ni), cobalt (Co), or a combination thereof. For example, the ferromagnetic pattern may include Co, CoPt, CoPd, or a combination thereof. According to some example embodiments, the anti-ferromagnetic pattern may include a non-magnetic material having anti-ferromagnetic coupling properties. For example, the anti-ferromagnetic pattern may include iridium (Ir), ruthenium (Ru), rhenium (Re), rhodium (Rh), tellurium (Te), yttrium (Y), chromium (Cr), silver (Ag), copper (Cu), or a combination thereof.

According to some example embodiments, the tunnel barrier pattern 164 may include an oxide material including Mg, Ti, Al, MgZn, MgB, Ti nitride, V nitride, or a combination thereof. For example, the tunnel barrier pattern 164 may include magnesium oxide (MgO), aluminum oxide (AlO), magnesium aluminum oxide (MgAlO), or a combination thereof.

Referring to FIG. 2A, the plurality of magnetic tunnel junction structures 160 may be spaced apart from each other in the horizontal direction (X direction and/or Y direction) with the isolation insulation layer 172 therebetween. According to some example embodiments, the isolation insulation layer 172 may surround the first electrode E1, the plurality of magnetic tunnel junction structures 160, and the second electrode E2 on the second interlayer insulation layer 123. According to some example embodiments, the isolation insulation layer 172 may include a portion extending into the second interlayer insulation layer 123 in the vertical direction (Z direction). According to some example embodiments, the top surface of the isolation insulation layer 172 may be coplanar with the top surface of the second electrode E2. According to some example embodiments, the isolation insulation layer 172 may include an oxide film, a nitride film, or a combination thereof.

According to some example embodiments, the magnetoresistive random access memory device 100 may include an upper insulation layer (not shown), which covers the top surface of the second electrode E2 and the upper surface of the isolation insulation layer 172, and a plurality of upper wiring structures 178, which penetrate the upper insulation layer (not shown), contact the second electrode E2, and extend long in the first horizontal direction (X direction). The plurality of upper wiring structures 178 may be spaced apart from each other in the second horizontal direction (Y direction) with the upper insulation layer therebetween and may extend parallel to each other. For example, the plurality of upper wiring structures 178 may correspond to the bit lines BL described above with reference to FIG. 1.

According to some example embodiments, the plurality of upper wiring structures 178 may contact the second electrode E2 on the plurality of magnetic tunnel junction structures 160. According to some example embodiments, the plurality of magnetic tunnel junction structures 160 each may be connected to one selected from among the plurality of upper wiring structures 178 through the second electrode E2.

According to some example embodiments, the plurality of upper wiring structures 178 may include a line barrier pattern 174 and a conductive line 176. The line barrier pattern 174 may include silver Ti, Ta, TiN, TaN, or a combination thereof, and the conductive line 176 may include W, Co, Cu, Ru, Mn, or a combination thereof.

Referring to FIG. 3A, the plurality of contact structures 155 may each include a first portion 155a having a sidewall facing the second interlayer insulation layer 123, and a second portion 155b having a sidewall facing the etch stop layer 118, and a third portion 155c extending into the wiring pattern 114. For example, the first portion 155a is disposed at a higher vertical level than the second portion 155b, the second portion 155b is disposed at a higher vertical level than the third portion 155c, and the first portion 155a, the second portion 155b, and the third portion 155c may be formed as one body (e.g., a single integral body). In this specification, the “vertical level” refers to a distance from the top surface 118U of the etch stop layer 118 in the vertical direction (−Z direction or Z direction). According to some example embodiments, the first portion 155a may be disposed at a higher vertical level than the top surface 118U of the etch stop layer 118, and the third portion 155c may be disposed at a vertical level lower than the top surface 118U of the etch stop layer 118 and being vertically opposite to the first portion 115a with respect to the second portion 155b.

According to some example embodiments, the first portion 155a may be in contact with the bottom surface of the first electrode E1 and may be surrounded by the second interlayer insulation layer 123 in the horizontal direction (X direction and/or Y direction). According to some example embodiments, the second portion 155b extends from the first portion 155a and may be surrounded by the etch stop layer 118 in the horizontal direction (X direction and/or Y direction). According to some example embodiments, the third portion 155c extends from the second portion 155b and may be surrounded by the wiring pattern 114. For example, the third portion 155c may have a side surface and a bottom surface facing the wiring pattern 114.

Referring to FIG. 3B, the second portion 155b may include an upper portion having a first horizontal width L2D1 in the first horizontal direction (X direction) and a lower portion disposed at a lower vertical level than the upper portion and having a second horizontal width L2D2 that is less than the first horizontal width L2D1 in the first horizontal direction (X direction). According to some example embodiments, the second portion 155b of each of the plurality of contact structures 155 may include an inflection portion FP defined between the upper portion and the lower portion of the second portion 155b. For example, the inflection portion FP may be disposed at a vertical level that is lower than the top surface 118U of the etch stop layer 118 and higher than the bottom surface of the etch stop layer 118.

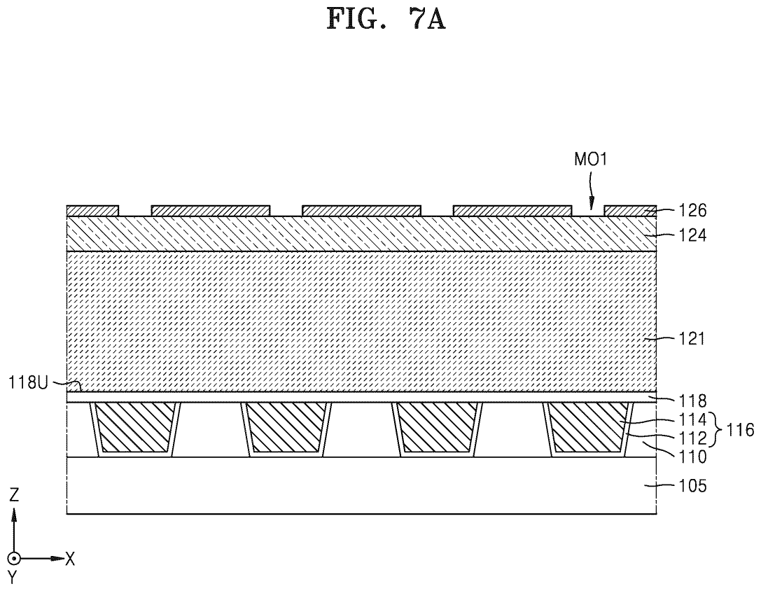

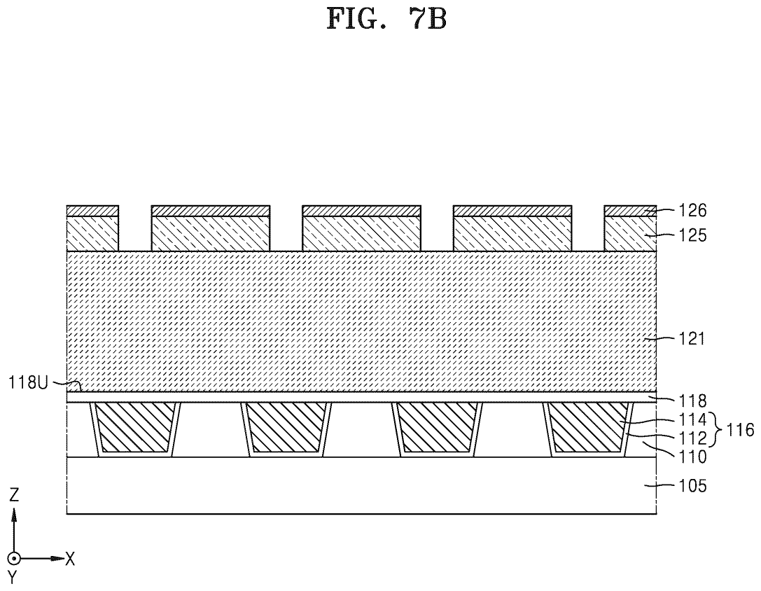

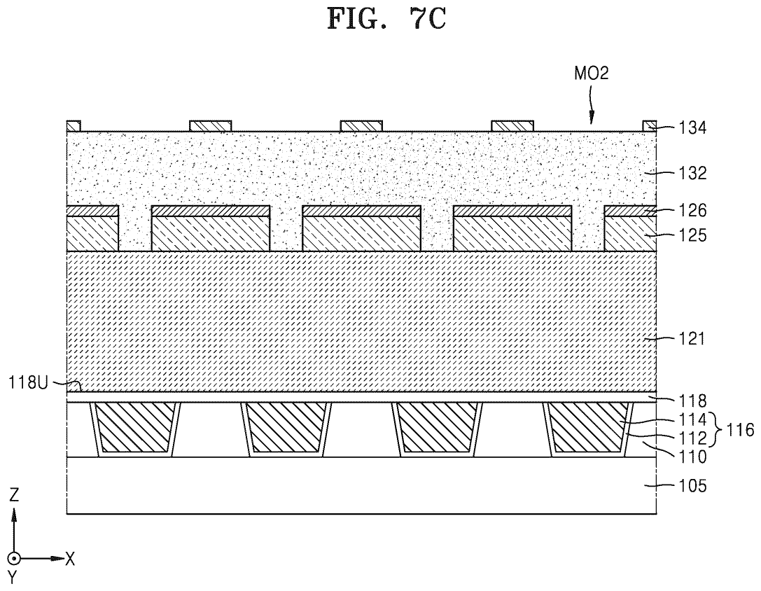

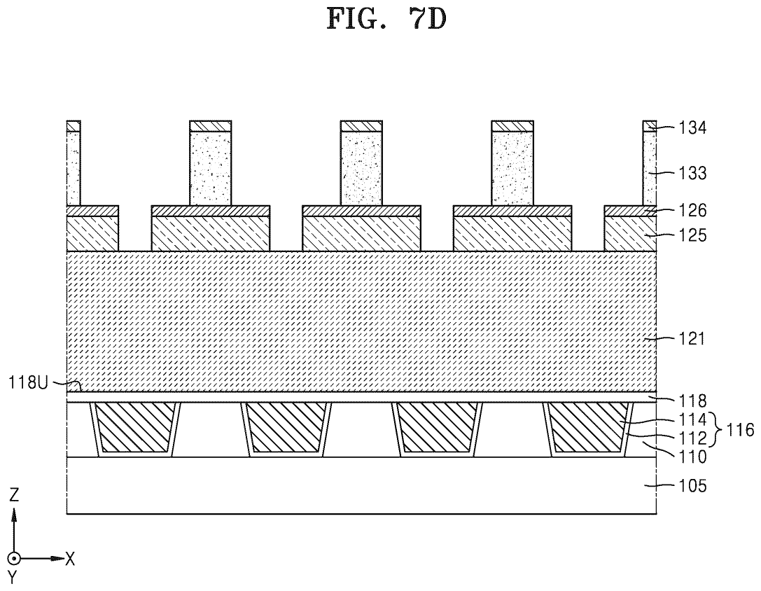

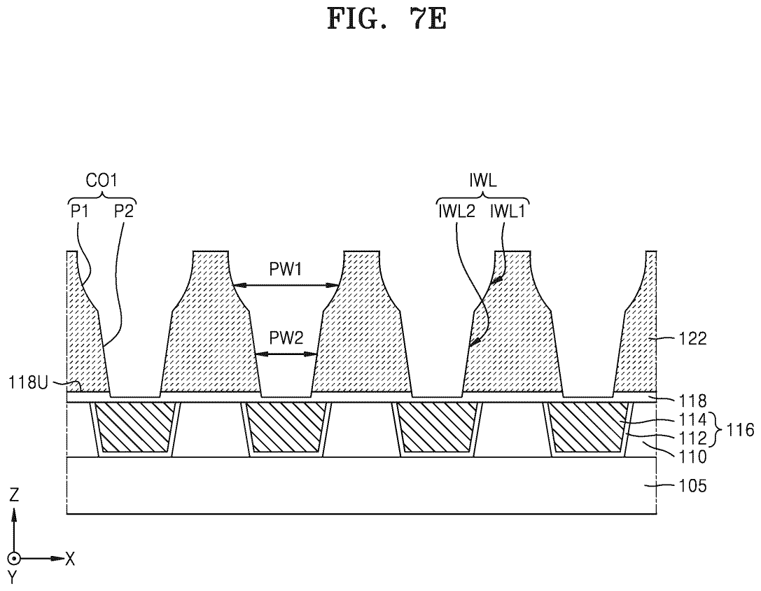

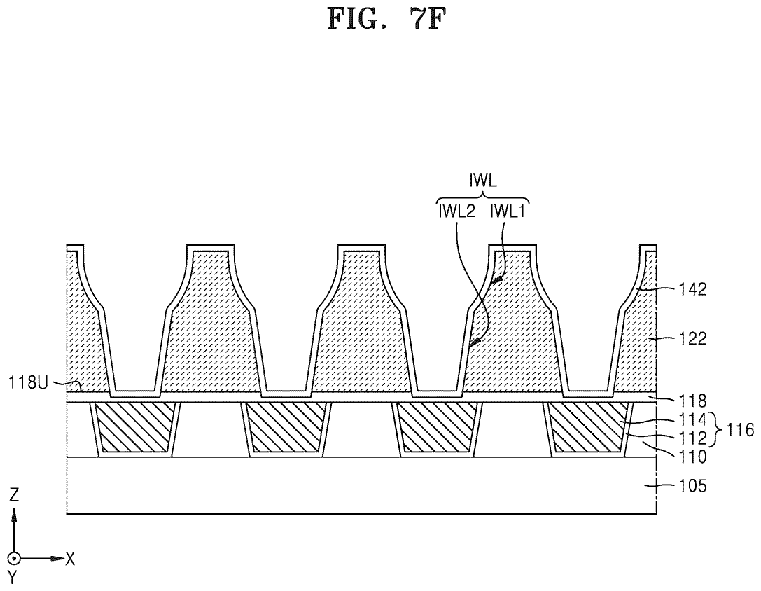

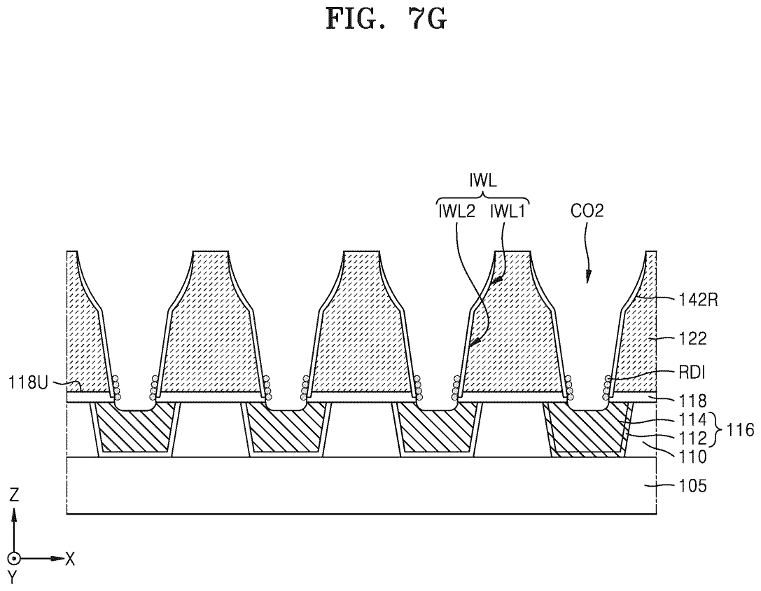

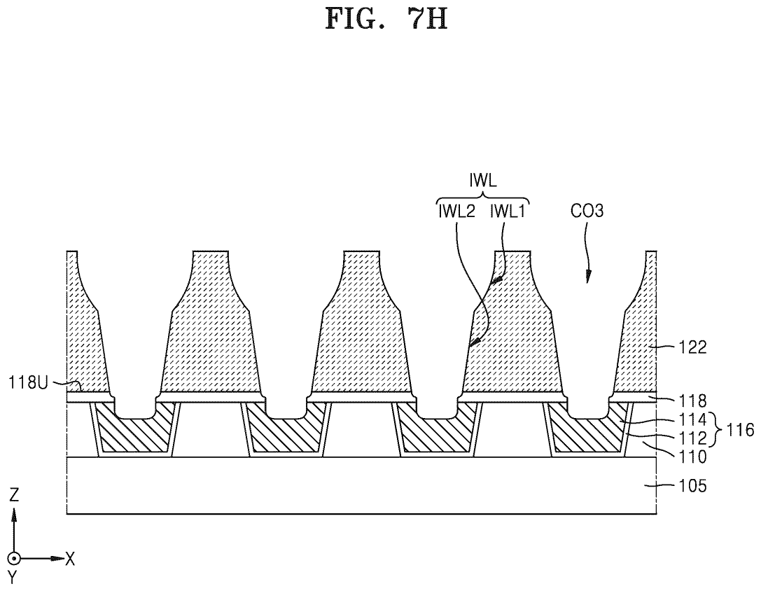

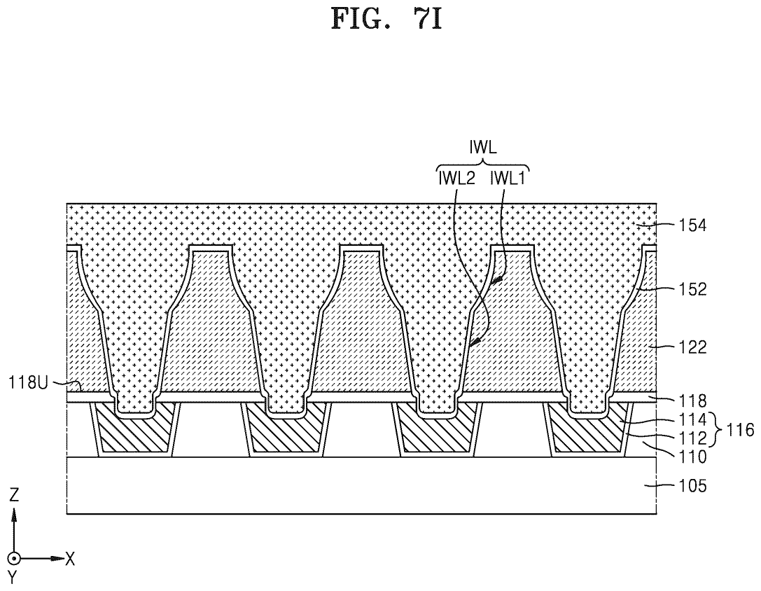

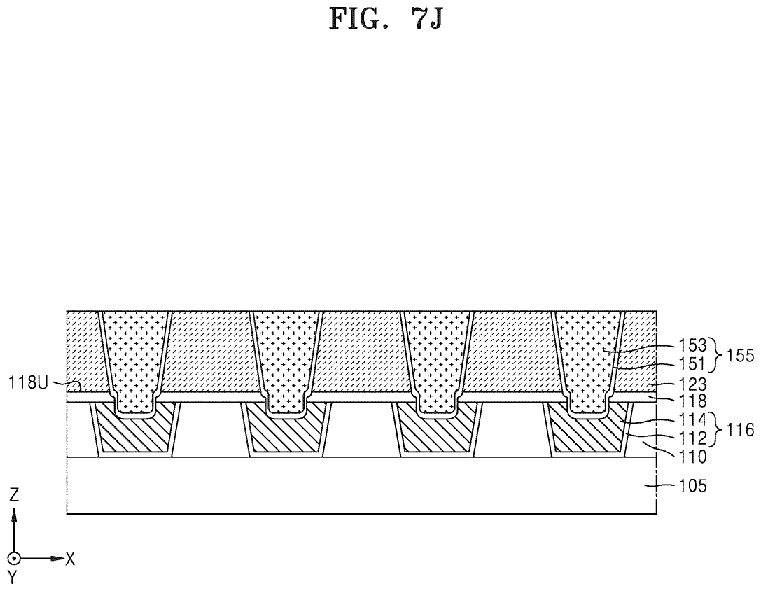

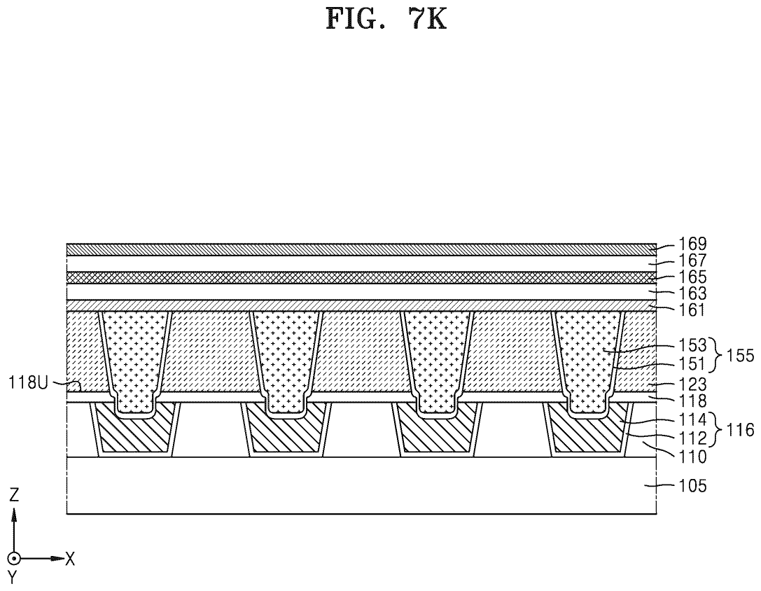

According to some example embodiments, a first contact width HD1, which is the width of the first portion 155a in the first horizontal direction (X direction), may be greater than a second contact width HD2, which is the width of the second portion 155b in the first horizontal direction (X direction). The plurality of contact structures 155 of the magnetoresistive random access memory device 100 according to some example embodiments each may include the second portion 155b having a horizontal width that is less than that of the first portion 155a at a lower vertical level than the second interlayer insulation layer 123, thereby alleviating or preventing reactive particles RDI (refer to FIG. 7G), which are formed from the wiring pattern 114 while forming the contact opening CO, from being deposited on the upper portion of the inner wall (e.g., inner boundary) of the contact opening CO.

According to some example embodiments, the sidewall of the first portion 155a may have a first angle θ1 with respect to a plane parallel to the top surface 118U of the etch stop layer 118. According to some example embodiments, the first portion 155a may have a tapered shape such that the width thereof in the first horizontal direction (X direction) decreases in a direction toward the top surface 118U of the etch stop layer 118. According to some example embodiments, the first angle θ1 may have an acute angle. According to some example embodiments, the first angle θ1 may be from about 65 degrees to about 85 degrees or from about 70 degrees to about 80 degrees. Within the above-stated range, in the process of forming the contact opening CO, a sufficient distance from the bottom surface (e.g., bottom) of the contact opening CO to the upper portion of the inner wall (e.g., inner boundary) of the contact opening CO (e.g., a portion of the contact opening CO having a vertical level higher than that of the top surface 118U of the etch stop layer 118) may be secured, thereby alleviating or preventing the reactive particles RDI from being deposited onto the upper portion of the inner wall (e.g., inner boundary) of the contact opening CO. Also, a separation distance between contact structures 155 adjacent to each other may be secured to block or prevent a short-circuit therebetween.

Referring to FIG. 3B, the sidewall of the lower portion of the second portion 155b may have a second angle θ2 with respect to a plane parallel to the top surface 118U of the etch stop layer 118. According to some example embodiments, the second angle θ2 may be greater than the first angle θ1.

According to some example embodiments, the sidewall of the upper portion of the second portion 155b may have an angle substantially equal to the first angle θ1 of the first portion 155a with respect to a plane parallel to the top surface 118U of the etch stop layer 118. For example, the sidewall of the upper portion of the second portion 155b may extend linearly from the sidewall of the first portion 155a.

According to some example embodiments, a third contact width HD3, which is the width of the third portion 155c in the first horizontal direction (X direction), may be less than the first contact width HD1. According to some example embodiments, the third contact width HD3 may be substantially equal to the second horizontal width L2D2 of the lower portion of the second portion 155b shown in FIG. 3B.

According to some example embodiments, a first vertical distance VD1, which is the distance in the vertical direction (Z direction) between the bottom surface of the etch stop layer 118 and the top surface of the plurality of contact structures 155, may be approximately about 70 nm or less. For example, the sum of the height of the first portion 155a of each of the plurality of contact structures 155 in the vertical direction (Z direction) and the height of the second portion 155b of each of the plurality of contact structures 155 in the vertical direction (Z direction) may be the first vertical distance VD1.

According to some example embodiments, the bottom surface of each of the plurality of contact structures 155 (e.g., the bottom surface of the third portion 155c) may be disposed at a vertical level lower than that of the bottom surface of the etch stop layer 118. According to some example embodiments, the bottom surface of the conductive plug 153 may be disposed at a vertical level lower than that of the bottom surface of the etch stop layer 118. The conductive plug 153 may include a portion that faces the wiring pattern 114 in the first horizontal direction (X direction) with the contact barrier pattern 151 therebetween.

The magnetoresistive random access memory device 100 according to some example embodiments includes the plurality of contact structures 155 penetrating portions of the second interlayer insulation layer 123, the etch stop layer 118, and the wiring pattern 114 in the vertical direction (Z direction) to contact the wiring structure 116, and the plurality of magnetic tunnel junction structures 160 may be connected to the wiring structure 116 through the plurality of contact structures 155. The first portion 155a of each of the plurality of contact structures 155 may have a horizontal width greater than that of the second portion 155b. Therefore, a sufficient distance from the bottom surface (e.g., bottom) of the contact opening CO to the upper portion of the inner wall (e.g., inner boundary) of the contact opening CO may be secured, and thus the reactive particles RDI (refer to FIG. 7G), which are formed from the wiring pattern 114 while forming the contact opening CO, may be alleviated or prevented from being deposited on the upper portion of the inner wall (e.g., inner boundary) of the contact opening CO and the reliability of the magnetoresistive random access memory device 100 may be improved.

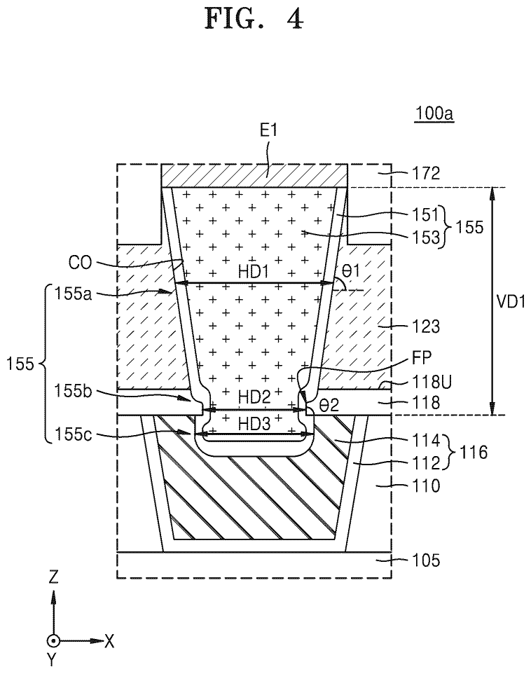

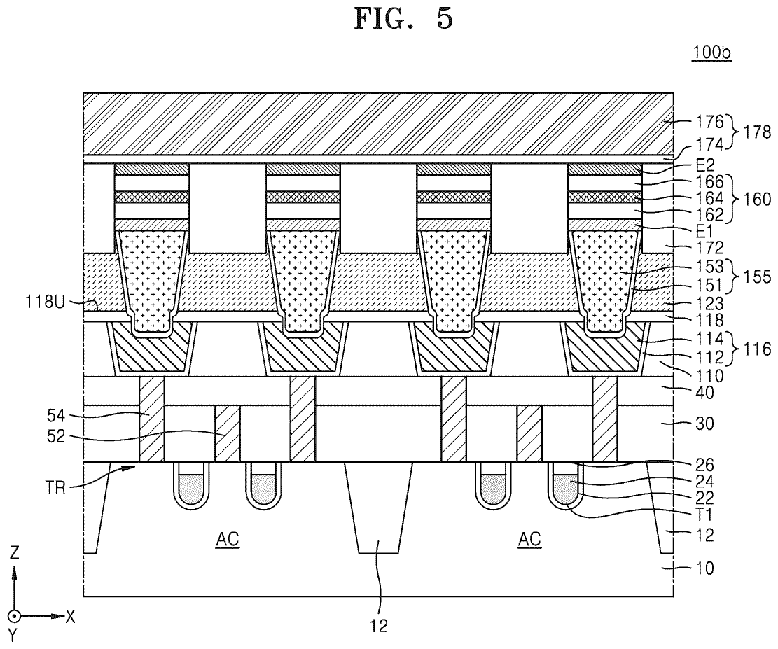

FIG. 4 is a cross-sectional view of a magnetoresistive random access memory device 100a according to an example and shows a region corresponding to the region EX1 in FIG. 2B. In FIG. 4, the same reference numerals as those in FIGS. 1 to 3B denote the same members, and detailed descriptions thereof will be omitted below.

Referring to FIG. 4, the second portion 155b of each of the plurality of contact structures 155 may include a portion having a width in the first horizontal direction (X direction) that is less than that of the third contact width HD3 of the third portion 155c. According to some example embodiments, referring to FIGS. 4 and 3B together, the third contact width HD3 of the third portion 155c may be greater than the second horizontal width L2D2 of the lower portion of the second portion 155b. For example, the plurality of contact structures 155 each may include a portion, in which the width thereof in the first horizontal direction (X direction) decreases as the plurality of contact structures 155 extend in the vertical direction (Z direction), and a portion, in which the width thereof in the first horizontal direction (X direction) increases as the plurality of contact structures 155 extend in the vertical direction (Z direction).

According to some example embodiments, the third portion 155c may include a portion that faces the bottom surface of the etch stop layer 118 in the vertical direction (Z direction). According to some example embodiments, the third portion 155c may include a portion that overlaps the upper portion of the second portion 155b, which is on the lower portion of the second portion 155b, in the vertical direction (Z direction) with the etch stop layer 118 therebetween. Therefore, it is possible to alleviate or prevent the materials constituting the wiring structure 116 from eluting between the contact barrier pattern 151 and the etch stop layer 118 and between the contact barrier pattern 151 and the second interlayer insulation layer 123, and thus the reliability of the magnetoresistive random access memory device 100a may be improved.

FIG. 5 is a cross-sectional view of a magnetoresistive random access memory device 100b according to an example embodiment. In FIG. 5, the same reference numerals as those in FIGS. 1 to 3B denote the same members, and detailed descriptions thereof will be omitted below.

Referring to FIG. 5, the magnetoresistive random access memory device 100b has substantially the same configuration as that described for the magnetoresistive random access memory device 100 with reference to FIGS. 1 to 3B. However, the magnetoresistive random access memory device 100b includes a substrate 10, transistors TR connected to the wiring structure 116, a source line 52, and a lower contact 54.

According to some example embodiments, the magnetoresistive random access memory device 100b may include the substrate 10 including an active region AC defined by a device isolation layer 12 and transistors TR formed on the substrate 10.

According to some example embodiments, the substrate 10 may include a semiconductor wafer. According to some example embodiments, the substrate 10 may include a semiconductor element such as Si or Ge or a compound semiconductor such as SiC, GaAs, InAs, and InP. According to some other example embodiments, the substrate 10 may have a silicon-on-insulator (SOI) structure. The substrate 10 may include a conductive region (e.g., a well doped with an impurity or a structure doped with an impurity). The device isolation layer 12 may include a silicon oxide film, but is not limited thereto.

According to some example embodiments, a gate trench T1 may be formed in the active region AC. According to some example embodiments, the magnetoresistive random access memory device 100b may include a gate dielectric layer 22 covering the inner wall of the gate trench T1, a gate line 24 disposed on the gate dielectric layer 22 and partially filling the interior of the gate trench T1, and a capping insulation layer 26 filling the rest of the gate trench T1 on the gate line 24. The gate line 24 may correspond to the word line WL of the magnetoresistive random access memory device 100 described above with reference to FIG. 1.

According to some example embodiments, the gate dielectric layer 22 may include at least one of among silicon oxide, silicon nitride, silicon oxynitride, oxide/nitride/oxide (ONO), or a high-k layer having a higher dielectric constant than silicon oxide. For example, the high-k layer may include at least one material of hafnium oxide (HfO), hafnium silicon oxide (HfSiO), hafnium oxynitride (HfON), hafnium silicon oxynitride (HfSiON), or zirconium oxide (ZrO), but is not limited thereto. According to some example embodiments, the gate line 24 may include Ti, TiN, Ta, TaN, W, WN, TiSiN, WSIN, or a combination thereof. According to some example embodiments, the capping insulation layer 26 may include a silicon oxide film, a silicon nitride film, a silicon oxynitride film, or a combination thereof.

According to some example embodiments, a first lower insulation layer 30 and a second lower insulation layer 40 may be sequentially stacked on the substrate 10 and the device isolation layer 12. According to some example embodiments, the magnetoresistive random access memory device 100b may include the source line 52 that penetrates the first lower insulation layer 30 and contacts a source region formed in a portion of the active region AC. For example, the source line 52 may extend long in the second horizontal direction (Y direction) on the source region. According to some example embodiments, the magnetoresistive random access memory device 100b may include the lower contact 54 that penetrates the first lower insulation layer 30 and the second lower insulation layer 40 and contacts a drain region formed in another portion of the active region AC. According to some example embodiments, one end of the lower contact 54 in the vertical direction (Z direction) may be connected to the drain region, and the other end of the lower contact 54 in the vertical direction (Z direction) may be connected to the wiring structure 116. According to some example embodiments, the source line 52 and the lower contact 54 may be insulated from each other by the first lower insulation layer 30 and the second lower insulation layer 40.

According to some example embodiments, the first lower insulation layer 30 and the second lower insulation layer 40 may each include an oxide film, a nitride film, or a combination thereof. According to some example embodiments, the source line 52 and the lower contact 54 each may include metal, conductive metal nitride, or a combination thereof.

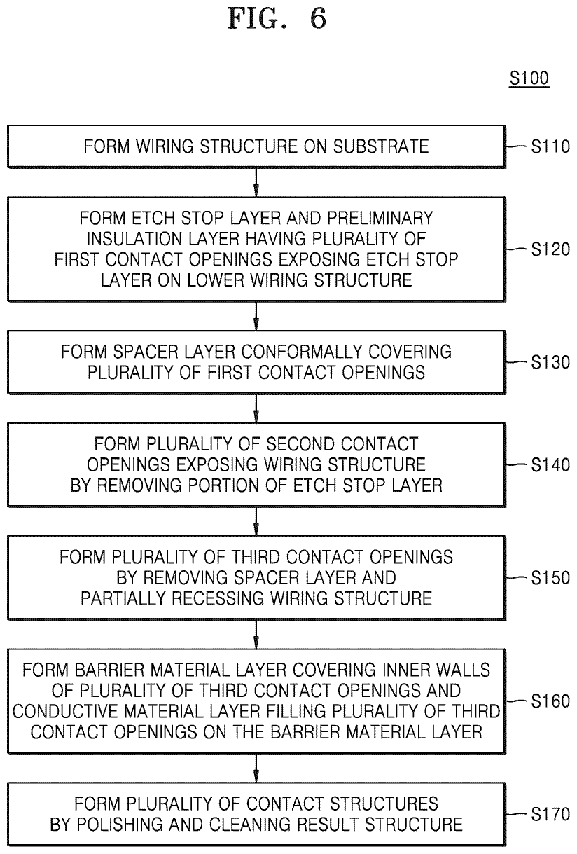

FIG. 6 is a flowchart of a method S100 of manufacturing a magnetoresistive random access memory device, according to an example embodiment.

Referring to FIG. 6, the method S100 of manufacturing a magnetoresistive random access memory, according to an example embodiment, may include operation S110 of forming a wiring structure on a substrate, operation S120 of forming, on the wiring structure, an etch stop layer and a preliminary insulation layer having a plurality of first contact openings exposing the etch stop layer, operation S130 of forming a spacer layer conformally covering the first contact openings, operation S140 of forming a plurality of second contact openings exposing the wiring structure by removing portions of the spacer layer and the etch stop layer, operation S150 of forming a plurality of third contact openings by removing the spacer layer, operation S160 of forming a barrier material layer covering the inner walls of the plurality of third contact openings and a conductive material layer on the barrier material layer, and operation S170 of forming a contact barrier pattern and a conductive plug by polishing and cleaning the resultant structure.

FIGS. 7A to 7K are cross-sectional views showing according to a process sequence the method S100 of manufacturing the magnetoresistive random access memory device 100 according to an example embodiment and are taken along a line X1-X1′ of FIG. 2A. Hereinafter, as an example, the method of the manufacturing the magnetoresistive random access memory device 100 shown in FIGS. 1 to 3B will be described with reference to FIGS. 6 and 7A to 7K.

Referring to FIGS. 6 and 7A, the wiring structure 116 may be formed on the substrate 105 (operation S110). According to some example embodiments, after an insulation material layer is formed on the substrate 105, a portion of the insulation material layer (not shown) may be removed to form the first interlayer insulation layer 110 having a wiring opening, and the wiring structure 116 may be formed by filling the wiring opening with the wiring barrier pattern 112 and the wiring pattern 114.

Thereafter, the etch stop layer 118 covering the first interlayer insulation layer 110 and the wiring structure 116 may be formed, and a first preliminary insulation layer 121, a first sacrificial layer 124 and a first mask pattern 126 having a first mask opening MO1 may be sequentially formed on the etch stop layer 118.

According to some example embodiments, the first preliminary insulation layer 121 may include a silicon oxide layer (e.g., TEOS). According to some example embodiments, the first sacrificial layer 124 may include a single layer or multiple layers. For example, the first sacrificial layer 124 may include a first lower sacrificial layer and a second lower sacrificial layer sequentially stacked on the first preliminary insulation layer 121. For example, the first lower sacrificial layer may include TiN and the second lower sacrificial layer may include SiON. According to some example embodiments, the first mask pattern 126 may include a photoresist film.

Referring to FIG. 7B, in the resultant structure of FIG. 7A, a first sacrificial pattern 125 may be formed by removing a portion of the first sacrificial layer 124 by using the first mask pattern 126 as an etch mask. For example, a portion of the first sacrificial layer 124 may be removed by a dry etching process to expose a portion of the top surface of the first preliminary insulation layer 121.

Referring to FIG. 7C, in the resultant structure of FIG. 7B, a second sacrificial layer 132 covering the first preliminary insulation layer 121, the first sacrificial pattern 125, and the first mask pattern 126 may be formed, and a second mask pattern 134 having a second mask opening MO2 may be formed on the second sacrificial layer 132.

According to some example embodiments, the second sacrificial layer 132 may cover a portion of the top surface of the first preliminary insulation layer 121 exposed by the first sacrificial pattern 125, the sidewall of the first sacrificial pattern 125, and the sidewall of the first mask pattern 126 and may be formed to have a sufficient thickness to cover the top surface of the first mask pattern 126. According to some example embodiments, the second sacrificial layer 132 may include a single layer or multiple layers. For example, the second sacrificial layer 132 may include a first upper sacrificial layer having a thickness sufficient to cover the top surface of the first mask pattern 126 and a second upper sacrificial layer on the first upper sacrificial layer. For example, the first upper sacrificial layer may include an amorphous carbon layer (ACL) or a spin-on hard mask. For example, the spin-on hard mask may be a carbon based spin-on hard mask (C-SOH). For example, the second lower sacrificial layer may include SiON. According to some example embodiments, the second mask pattern 134 may include a photoresist film.

Referring to FIG. 7D, in the resultant structure of FIG. 7C, a portion of the second sacrificial layer 132 may be removed by using the second mask pattern 134 as an etch mask to form a second sacrificial pattern 133. According to some example embodiments, the second sacrificial layer 132 may be removed by a dry etching process. Here, a portion of the first mask pattern 126 and the sidewall of the first sacrificial pattern 125 may be exposed.

Referring to FIG. 7E, in the resultant structure of FIG. 7D, a portion of the first preliminary insulation layer 121 may be removed through an etch-back process, thereby forming a second preliminary insulation layer 122 having a plurality of first contact openings CO1 exposing the etch stop layer 118 (operation S120). According to some example embodiments, the second mask pattern 134, the second sacrificial pattern 133, the first mask pattern 126, and the first sacrificial pattern 125 may serve as an etching mask for forming the plurality of first contact openings CO1. According to some example embodiments, in the etch-back process, at least a portion of the second mask pattern 134, at least a portion of the second sacrificial pattern 133, at least a portion of the first mask pattern 126, and at least a portion of the first sacrificial pattern 125 may be removed. According to some example embodiments, portions of the second mask pattern 134, the second sacrificial pattern 133, the first mask pattern 126, and the first sacrificial pattern 125 may not be removed and remain as residual films. In this case, the remaining residual films may be removed through a separate stripping process. According to some example embodiments, a portion of the etch stop layer 118 may be removed in this process. For example, the bottom surfaces (e.g., bottom) of the plurality of first contact openings CO1 may be arranged at a vertical level lower than that of the top surface 118U of the etch stop layer 118.

According to some example embodiments, the plurality of first contact openings CO1 may each include an upper portion P1 having a relatively wide horizontal width and a lower portion P2 having a horizontal width that is less than that of the first portion P1, to correspond to the profile of a mask structure including the second mask pattern 134, the second sacrificial pattern 133, the first mask pattern 126, and the first sacrificial pattern 125. According to some example embodiments, a first opening width PW1, which is the width of the upper portion P1 in the first horizontal direction (X direction), may be greater than a second opening width PW2, which is the width of the lower portion P2 in the first horizontal direction (X direction).

According to some example embodiments, the second preliminary insulation layer 122 may have an opening inner wall IWL defining the plurality of first contact openings CO1, and the opening inner wall IWL may include a first inner wall IWL1 defining the upper portion P1 and a second inner wall IWL2 defining the lower portion P2. According to some example embodiments, the first inner wall IWL1 may have a rounded concave profile, and the width of the upper portion P1 of each of the plurality of first contact openings CO1 in the first horizontal direction (X direction) may gradually increase as the distance from the top surface 118U of the etch stop layer 118 increases. According to some example embodiments, the second inner wall IWL2 may extend linearly, and the width of the lower portion P2 of each of the plurality of first contact openings CO1 in the first horizontal direction (X direction) may gradually increase as the distance from the top surface 118U of the etch stop layer 118 increases. According to some example embodiments, at a point where the first inner wall IWL1 and the second inner wall IWL2 meet each other, the slope of the first inner wall IWL1 with respect to the top surface 118U of the etch stop layer 118 may be less than the slope of the second inner wall IWL2 with respect to the top surface 118U of the etch stop layer 118.

Referring to FIG. 7F, in the resultant structure of FIG. 7D, a spacer layer 142 conformally covering the inner walls (e.g., inner boundaries) and the bottom surfaces (e.g., bottoms) of the plurality of first contact openings CO1 may be formed (operation S130). The spacer layer 142 may cover a portion of the etch stop layer 118 exposed through the plurality of first contact openings CO1, the opening inner wall IWL, and the top surface of the second preliminary insulation layer 122.

According to some example embodiments, the spacer layer 142 may be formed by an atomic layer deposition (ALD) process. According to some example embodiments, the spacer layer 142 may include TiN.

Referring to FIG. 7G, a portion of the spacer layer 142 and a portion of the etch stop layer 118 may be removed in the resultant structure of FIG. 7F to form a plurality of second contact openings CO2 exposing the wiring pattern 114 (operation S140).

According to some example embodiments, in the process of forming the plurality of second contact openings CO2, a portion of the spacer layer 142 may be removed to form a remaining spacer layer 142R. For example, the remaining spacer layer 142R may cover the opening inner wall IWL. For example, the plurality of second contact openings CO2 may be defined by the remaining spacer layer 142R, the etch stop layer 118, and the wiring pattern 114.

According to some example embodiments, in the process of forming the plurality of second contact openings CO2, a portion of the wiring pattern 114 may be removed and the bottom surfaces (e.g., bottoms) of the plurality of second contact openings CO2 may be located at a vertical level lower than that of the bottom surface of the etch stop layer 118. According to some other example embodiments, the bottom surfaces (e.g., bottoms) of the plurality of second contact openings CO2 may be located at substantially the same vertical level as the bottom surface of the etch stop layer 118.

According to some example embodiments, in the etching process to expose the wiring pattern 114, the reactive particles RDI including a metal material constituting the wiring pattern 114 and/or an oxide of the metal material may be generated and deposited on the inner walls of the plurality of second contact openings CO2. For example, the reactive particles RDI may be deposited on the remaining spacer layer 142R. According to the method S100 of manufacturing a magnetoresistive random access memory device, according to some example embodiments, the spacer layer 142 covering the inner walls and the bottom surfaces of the plurality of first contact openings CO1 may be formed before exposing the wiring pattern 114, thereby alleviating or preventing the reactive particles RDI from being deposited on the inner wall of the second preliminary insulation layer 122. Therefore, the problem of deterioration of adhesion between the contact barrier pattern 151 (refer to FIGS. 2B and 3A) and the second interlayer insulation layer 123 (refer to FIGS. 2B and 3A) due to the reactive particles RDI between the contact barrier pattern 151 and the second interlayer insulation layer 123 may be prevented or alleviated. Therefore, the problem of defects occurring due to the material constituting the wiring pattern 114 being eluted through the space between the contact barrier pattern 151 and the second interlayer insulation layer 123 may be prevented or alleviated, and thus a magnetoresistive random access memory having improved reliability may be manufactured.

Referring to FIG. 7H, in the resultant structure of FIG. 7G, the remaining spacer layer 142R may be removed through a cleaning process, and the wiring pattern 114 may be partially recessed to form a plurality of third contact openings CO3 (operation S150). The reactive particles RDI may be removed together with the remaining spacer layer 142R. According to some example embodiments, in the cleaning process, a portion of the wiring pattern 114 may be removed through wet etching using a cleaning solution. According to some example embodiments, the bottom surfaces of the plurality of third contact openings CO3 may be disposed at a vertical level lower than that of the bottom surface of the etch stop layer 118. Therefore, a path for diffusion of the reactive particles RDI that may occur during the cleaning process may be secured at a vertical level lower than that of the bottom surface of the etch stop layer 118, thereby suppressing deposition of the reactive particles RDI on the opening inner wall IWL of the second preliminary insulation layer 122.

According to some example embodiments, the opening inner wall IWL of the second preliminary insulation layer 122, the inner wall of the etch stop layer 118, and the recessed portion of the wiring pattern 114 may be exposed through the plurality of third contact openings CO3. In the opening inner wall IWL, the second inner wall IWL2 may have a profile corresponding to the sidewall of the first portion 155a of the plurality of contact structures 155 described above with reference to FIGS. 1 to 3B, the inner wall of the etch stop layer 118 may have a profile corresponding to the sidewall of the second portion 155b, and the recessed portion of the wiring pattern 114 may have a profile corresponding to the sidewall and the bottom surface of the third portion 155c.

Referring to FIG. 7I, in the resultant structure of FIG. 7H, a barrier material layer 152 covering the inner walls and the bottom surfaces of the plurality of third contact openings CO3 may be formed, and a conductive material layer 154 having a sufficient thickness to fill the plurality of third contact openings CO3 may be formed on the barrier material layer 152. For example, the conductive material layer 154 may include a portion that covers the top surface of the second preliminary insulation layer 122.

According to some example embodiments, the barrier material layer 152 may be formed by a physical vapor deposition (PVD) process. According to some example embodiments, a portion of the barrier material layer 152 that covers the first inner wall IWL1 may be formed to be thicker than a portion of the barrier material layer 152 that covers the second inner wall IWL2. Therefore, adhesion between the first inner wall IWL1 close to the top surface of the second preliminary insulation layer 122 and the second preliminary insulation layer 122 may be improved.

Referring to FIG. 7J, the top surface of the resultant structure of FIG. 7I may be removed through a CMP process to form the contact barrier pattern 151 and the conductive plug 153 (operation S170). According to some example embodiments, a cleaning process may be performed together with the CMP process. For example, a cleaning solution used in the cleaning process may include HF.

According to some example embodiments, the upper portion of the second preliminary insulation layer 122 (e.g., the portion having the first inner wall IWL1) may be removed through the CMP process, and thus the second interlayer insulation layer 123 may be formed. The upper portion having the first inner wall IWL1 may form adhesion with the barrier material layer 152 having a relatively large thickness, and thus the problem in which the barrier material layer 152 is lifted as the cleaning solution penetrates between the second preliminary insulation layer 122 and the barrier material layer 152 in the CMP process including cleaning and the problem in which the material constituting the wiring pattern 114 is eluted due to the cleaning solution may be prevented or alleviated.

Referring to FIG. 7K, in the resultant structure of FIG. 7J, a first conductive layer 161, a first magnetic layer 163, a tunnel barrier layer 165, a second magnetic layer 167, and a second conductive layer 169 may be sequentially formed on the plurality of contact structures 155 and the second interlayer insulation layer 123.

Referring to FIG. 7K and FIGS. 1 to 3B together, in the resultant structure of FIG. 7K, portions of the first conductive layer 161, the first magnetic layer 163, the tunnel barrier layer 165, the second magnetic layer 167 may be removed, thereby forming the first electrode E1, the plurality of magnetic tunnel junction structures 160, and the second electrode E2. Thereafter, the magnetoresistive random access memory device 100 may be formed by forming the isolation insulation layer 172 and the plurality of upper wiring structures 178 on the second interlayer insulation layer 123.

While the inventive concepts has been particularly shown and described with reference to some example embodiments thereof, it will be understood that various changes in form and details may be made therein without departing from the spirit and scope of the following claims.

What is claimed is:

1. A magnetoresistive random access memory device comprising:
a wiring structure on a substrate;
an etch stop layer on the wiring structure;
an interlayer insulation layer on the etch stop layer;
a plurality of contact structures penetrating the interlayer insulation layer and the etch stop layer to contact the wiring structure, each of the plurality of contact structures comprising a first portion having a sidewall facing the interlayer insulation layer and a second portion having a sidewall facing the etch stop layer; and
a plurality of magnetic tunnel junction structures on the plurality of contact structures and connected to corresponding ones of the plurality of contact structures, respectively,
wherein a first width of the first portion in a first horizontal direction is greater than a second width of the second portion in the first horizontal direction.

2. The magnetoresistive random access memory device of claim 1, wherein the second portion comprises:
a lower portion;
an upper portion on the lower portion and having a greater width in the first horizontal direction than the lower portion; and
an inflection portion defined between the lower portion and the upper portion.

3. The magnetoresistive random access memory device of claim 2, wherein
the sidewall of the first portion has a first angle with respect to a top surface of the etch stop layer,
a sidewall of the lower portion of the second portion has a second angle with respect to the top surface of the etch stop layer, and
the second angle is greater than the first angle.

4. The magnetoresistive random access memory device of claim 2, wherein a sidewall of the upper portion of the second portion linearly extends from the sidewall of the first portion.

5. The magnetoresistive random access memory device of claim 1, wherein the sidewall of the first portion has an angle from about 70 degrees to about 80 degrees with respect to a top surface of the etch stop layer.

6. The magnetoresistive random access memory device of claim 1, wherein each of the plurality of contact structures comprises a third portion extending from the second portion into the wiring structure.

7. The magnetoresistive random access memory device of claim 6, wherein the third portion comprises a portion that faces a bottom surface of the etch stop layer in a vertical direction.

8. The magnetoresistive random access memory device of claim 6, wherein the second portion comprises:
a lower portion;
an upper portion on the lower portion and having a greater width in the first horizontal direction than the lower portion; and
an inflection portion defined between the lower portion and the upper portion, and
a third width of the third portion in the first horizontal direction is greater than a width of the lower portion of the second portion in the first horizontal direction.

9. The magnetoresistive random access memory device of claim 1, wherein a vertical distance from a bottom surface of the etch stop layer to top surfaces of the plurality of contact structures is about 70 nm or less.

10. A magnetoresistive random access memory device comprising:
a wiring structure on a substrate;
an etch stop layer on the wiring structure;
an interlayer insulation layer on the etch stop layer;
a plurality of contact structures penetrating the interlayer insulation layer, the etch stop layer, and a portion of the wiring structure to contact the wiring structure, each of the plurality of contact structures comprising a first portion having a sidewall facing the interlayer insulation layer, a second portion having a sidewall facing the etch stop layer, and a third portion extending into the wiring structure; and
a plurality of magnetic tunnel junction structures on the plurality of contact structures and connected to corresponding ones of the plurality of contact structures, respectively,
wherein the second portion comprises a lower portion, an upper portion on the lower portion, and an inflection portion defined between the lower portion and the upper portion, the upper portion having a greater width in a first horizontal direction than the lower portion, and
the sidewall of the first portion has a first angle with respect to a top surface of the etch stop layer, a sidewall of the lower portion of the second portion has a second angle with respect to the top surface of the etch stop layer, and the second angle is greater than the first angle.

11. The magnetoresistive random access memory device of claim 10, wherein the third portion comprises a portion that overlaps the upper portion of the second portion in a vertical direction.

12. The magnetoresistive random access memory device of claim 10, wherein the first portion has a tapered shape such that a width thereof in the first horizontal direction decreases in a direction toward the top surface of the etch stop layer.

13. The magnetoresistive random access memory device of claim 10, wherein
the upper portion of the sidewall of the second portion has a third angle with respect to a top surface of the etch stop layer, and
the third angle is substantially equal to the first angle.

14. A method of manufacturing a magnetoresistive random access memory device, the method comprising:
forming a wiring structure on a substrate;
forming, on the wiring structure, an etch stop layer and a preliminary insulation layer, which includes a plurality of first contact openings exposing the etch stop layer, on the wiring structure;
forming a spacer layer conformally covering the plurality of first contact openings;
forming a plurality of second contact openings exposing the wiring structure by removing a portion of the spacer layer and the etch stop layer;
forming a plurality of third contact openings by removing the spacer layer; and
forming a plurality of contact structures filling the plurality of third contact openings, respectively.

15. The method of claim 14, wherein
each of the plurality of first contact openings comprise,
a lower portion exposing the etch stop layer, and
an upper portion on the lower portion and having a width in a first horizontal direction greater than that of the lower portion, and
at a point where the lower portion and the upper portion meet each other,
a first side boundary of the upper portion has a first slope with respect to a top surface of the etch stop layer,
a second side boundary of the lower portion has a second slope with respect to the top surface of the etch stop layer, and
the first slope is less than the second slope.

16. The method of claim 15, wherein the upper portion is removed during the forming of the plurality of contact structures.

17. The method of claim 15, wherein the first side boundary has a rounded concave profile.

18. The method of claim 15, wherein
the second side boundary extends linearly, and
a width of the lower portion in the first horizontal direction gradually increases as a distance from the top surface of the etch stop layer increases.

19. The method of claim 14, wherein bottoms of the plurality of second contact openings are at a vertical level lower than that of a bottom surface of the etch stop layer.

20. The method of claim 14, wherein the forming of the preliminary insulation layer comprises:
sequentially forming an insulation layer, a first sacrificial layer, and a first mask pattern on the etch stop layer;
forming a first sacrificial pattern by removing a portion of the first sacrificial layer by using the first mask pattern as an etch mask;
sequentially forming a second sacrificial layer and a second mask pattern on the insulation layer, the first sacrificial pattern, and the first mask pattern;
forming a second sacrificial pattern by removing a portion of the second sacrificial layer by using the second mask pattern as an etch mask; and
forming a plurality of first contact openings by removing a portion of the insulation layer through an etch-back process.
